(19) United States
(12) Patent Application Publication
(10) Pub. No.: US 2026/0150283 A1
(43) Pub. Date: May 28, 2026

(54) SEMICONDUCTOR STORAGE DEVICE

(71) Applicant: Kioxia Corporation, Minato-ku, Tokyo (JP)

(72) Inventors: Hiroiki HAYAKAWA, Yokkaichi Mie (JP); Takamitsu OCHI, Nagoya Aichi (JP); Keiki NAGAI, Yokkaichi Mie (JP); Yusuke MORI, Yokkaichi Mie (JP)

(73) Assignee: Kioxia Corporation, Minato-ku, Tokyo (JP)

(21) Appl. No.: 19/114,585

(22) PCT Filed: Sep. 26, 2022
(86) PCT No.: PCT/JP2022/035634

§ 371 Date: Mar. 24, 2025

(51) Int. Cl. H10B 41/35; H10B 41/27

(52) U.S. Cl. CPC H10B 41/35; H10B 41/27

(57) ABSTRACT

A semiconductor storage device of an embodiment has a substrate, a first interconnection, a second interconnection, a channel portion, first charge storage portions, and second charge storage portions. The first interconnection extends in a first direction, and the second interconnection is adjacent to the first interconnection in a second direction intersecting the first direction and extends in the first direction. The channel portion is provided between the first interconnection and the second interconnection and extends in a third direction intersecting the first direction and the second direction. The first charge storage portions are provided between the first interconnection and the channel portion. The second charge storage portions are provided between the second interconnection and the channel portion.

### TECHNICAL FIELD

The present invention relates to a semiconductor storage device.

### BACKGROUND ART

A semiconductor storage device has been proposed which has: a multi-layered body including insulating films and word lines which are alternately stacked; and a semiconductor pillar penetrating the multi-layered body. Incidentally, further improvement in electrical characteristics are expected for semiconductor storage devices.

### CITATION LIST

### Patent Document

Patent Document 1: United States Patent Application, Publication No. 2016/0336336

### SUMMARY OF INVENTION

### Technical Problem

A problem to be solved by the present invention is to provide a semiconductor storage device capable of improving electrical characteristics.

### Solution to Problem

A semiconductor storage device of an embodiment has a substrate, a first interconnection, a second interconnection, a channel portion, first charge storage portions, second charge storage portions, first insulating films, and second insulating films. The first interconnection extends in a first direction. The second interconnection is adjacent to the first interconnection in a second direction intersecting the first direction and extends in the first direction. The channel portion is provided between the first interconnection and the second interconnection and extends in a third direction intersecting the first direction and the second direction. The first charge storage portions are provided between the first interconnection and the channel portion. The second charge storage portions are provided between the second interconnection and the channel portion. The first insulating films are provided between the first charge storage portions and the channel portion. The second insulating films are provided between the second charge storage portions and the channel portion. The first charge storage portions adjacent to each other in the third direction are provided such that a first gap is formed between the first charge storage portions adjacent to each other in the third direction. The second charge storage portions adjacent to each other in the third direction are provided such that a second gap is formed between the second charge storage portions adjacent to each other in the third direction. A first impurity diffusion region in which an impurity element is diffused is provided inside the channel portion between the first charge storage portions adjacent to each other in the third direction. A second impurity diffusion region in which an impurity element is diffused is provided inside the channel portion between the second charge storage portions adjacent to each other in the third direction.

### BRIEF DESCRIPTION OF DRAWINGS

FIG. 1 A perspective view showing a configuration of a semiconductor storage device of an embodiment.

FIG. 2 A cross-sectional view of a region surrounded by a two-dot chain line F2 of the semiconductor storage device shown in FIG. 1.

FIG. 3 A cross-sectional view along line F3-F3 of the semiconductor storage device shown in FIG. 2.

FIG. 4 An enlarged cross-sectional view showing a first floating gate electrode FGA shown in FIG. 2 and a vicinity thereof.

FIG. 5 A view showing a manufacturing method of the semiconductor storage device of the embodiment.

FIG. 6 A view showing the manufacturing method of the semiconductor storage device of the embodiment.

FIG. 7 A view showing the manufacturing method of the semiconductor storage device of the embodiment.

FIG. 8 A view showing the manufacturing method of the semiconductor storage device of the embodiment.

FIG. 9 A view showing the manufacturing method of the semiconductor storage device of the embodiment.

FIG. 10 A view showing the manufacturing method of the semiconductor storage device of the embodiment.

FIG. 11 A view showing the manufacturing method of the semiconductor storage device of the embodiment.

FIG. 12 A view showing the manufacturing method of the semiconductor storage device of the embodiment.

FIG. 13 A view showing the manufacturing method of the semiconductor storage device of the embodiment.

FIG. 14 A view showing the manufacturing method of the semiconductor storage device of the embodiment.

FIG. 15 A view showing the manufacturing method of the semiconductor storage device of the embodiment.

FIG. 16 A view showing the manufacturing method of the semiconductor storage device of the embodiment.

FIG. 17 A view showing the manufacturing method of the semiconductor storage device of the embodiment.

FIG. 18 A view showing the manufacturing method of the semiconductor storage device of the embodiment.

FIG. 19 A view showing the manufacturing method of the semiconductor storage device of the embodiment.

FIG. 20 A view showing the manufacturing method of the semiconductor storage device of the embodiment.

FIG. 21 A view showing the manufacturing method of the semiconductor storage device of the embodiment.

FIG. 22 A view showing the manufacturing method of the semiconductor storage device of the embodiment.

FIG. 23 A view showing the manufacturing method of the semiconductor storage device of the embodiment.

FIG. 24 A view showing the manufacturing method of the semiconductor storage device of the embodiment.

FIG. 25 A view showing the manufacturing method of the semiconductor storage device of the embodiment.

FIG. 26 A view showing the manufacturing method of the semiconductor storage device of the embodiment.

FIG. 27 A view showing the manufacturing method of the semiconductor storage device of the embodiment.

FIG. 28 A view showing the manufacturing method of the semiconductor storage device of the embodiment.

FIG. 29 A view showing the manufacturing method of the semiconductor storage device of the embodiment.

FIG. 30 A cross-sectional view showing a semiconductor storage device of a modified example of the embodiment.

### DESCRIPTION OF EMBODIMENTS

Hereinafter, a semiconductor storage device of an embodiment will be described with reference to the drawings. In the following description, components having the same or similar functions are denoted by the same reference signs. Also, duplicate description of the components may be omitted. The drawings are schematic or conceptual, and a relationship between a thickness and a width of each portion, a size ratio between portions, and the like are not necessarily the same as actual ones.

In the present specification, “connection” is not limited to a case of being physically connected, and also includes a case of being electrically connected. That is, “connection” is not limited to a case in which two members are in contact with each other, but also includes a case in which another member is interposed between the two members. “Facing” is not limited to two members directly facing each other, but also includes a case in which another member is present between the two members. “Facing” also includes a case in which parts of two members face each other. “XX is provided on YY” is not limited to a case in which XX is in contact with YY, but also includes a case in which another member is interposed between XX and YY. “Annular” is not limited to a circular annular shape, and also includes a rectangular annular shape. In the present specification, “adjacent” is not limited to a case of being adjacent, and also includes a case in which another element is present between two target elements. “Parallel”, “orthogonal”, or “the same” includes a case of “substantially parallel”, “substantially orthogonal”, or “substantially the same”. “Extending in an A direction” means that, for example, a dimension in the A direction is larger than a minimum dimension of dimensions in an X direction, a Y direction, and a Z direction to be described below. The “A direction” described herein is an arbitrary direction.

First, a +X direction, a −X direction, a +Y direction, a −Y direction, a +Z direction, and a −Z direction will be defined. The +X direction, the −X direction, the +Y direction, and the −Y direction are directions along a surface of a silicon substrate 10 to be described later. The +X direction is one of directions in which a bit line BL to be described later extends. The −X direction is a direction opposite to the +X direction. In a case in which the +X direction and the −X direction do not need to be distinguished from each other, they will be simply referred to as the “X direction”. The +Y direction and the −Y direction are directions intersecting (for example, orthogonal to) the X direction. The +Y direction is one of directions in which a word line interconnection WL to be described later extends. The −Y direction is a direction opposite to the +Y direction. In a case in which the +Y direction and the −Y direction do not need to be distinguished from each other, they will be simply referred to as the “Y direction”. The +Z direction and the −Z direction are directions intersecting (for example, orthogonal to) the X direction and the Y direction, and are a thickness direction of the silicon substrate 10. The +Z direction is a direction toward a multi-layered body 50 to be described later from the silicon substrate 10. The −Z direction is a direction opposite to the +Z direction. In a case in which the +Z direction and the −Z direction do not need to be distinguished from each other, they will be simply referred to as the “Z direction”. The Z direction corresponds to a direction perpendicular to the surface of the silicon substrate 10 used to form a semiconductor storage device 1. In the present specification, the “+Z direction” may be referred to using “upward”, and the “−Z direction” may be referred to using “downward”. However, these expressions are for convenience only and do not define a direction of gravity. The +Y direction is an example of a “first direction”. The +X direction is an example of a “second direction”. The +Z direction is an example of a “third direction”.

In each of a plan view and a cross-sectional view of the drawings referred to below, illustration of some components such as interconnections, contacts, and interlayer insulating films may be omitted as appropriate for easy viewing of the drawings.

### Embodiment

### 1. Overall Configuration of Semiconductor Storage Device

First, an overall configuration of a semiconductor storage device 1 of the embodiment will be described. The semiconductor storage device 1 is a nonvolatile semiconductor storage device and is, for example, a NAND-type flash memory.

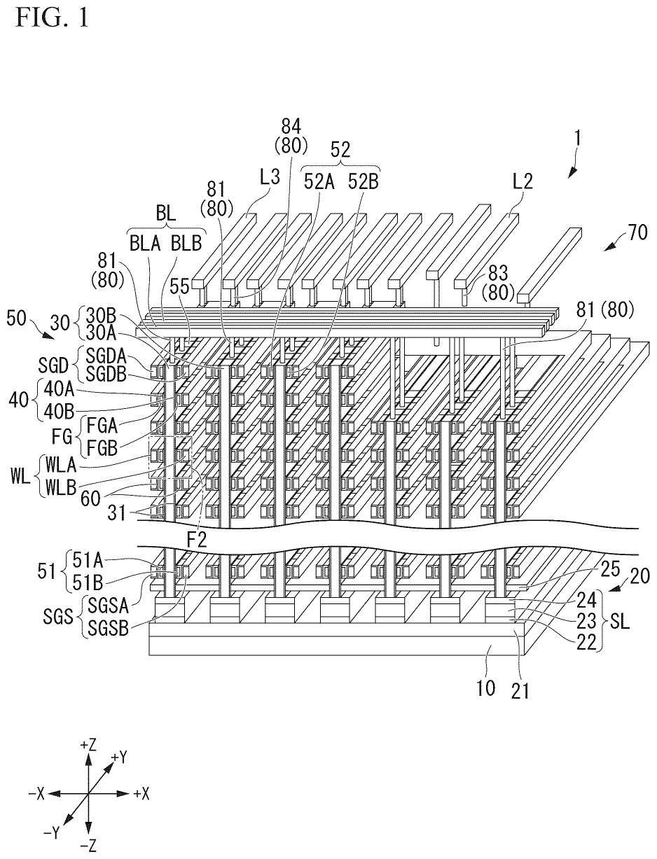

FIG. 1 is a perspective view showing a configuration of the semiconductor storage device 1. The semiconductor storage device 1 includes, for example, a silicon substrate 10, a lower structure 20, a plurality of pillars (pillar members) 30, a plurality of tunnel insulating films 40, a multi-layered body 50, an upper structure 70, and a plurality of contacts 80.

The silicon substrate 10 is a substrate serving as a base of the semiconductor storage device 1. At least a part of the silicon substrate 10 is formed in a plate shape extending in the X direction and Y direction. The silicon substrate 10 is formed of, for example, a semiconductor material containing silicon (Si). The silicon substrate 10 is an example of a “substrate”.

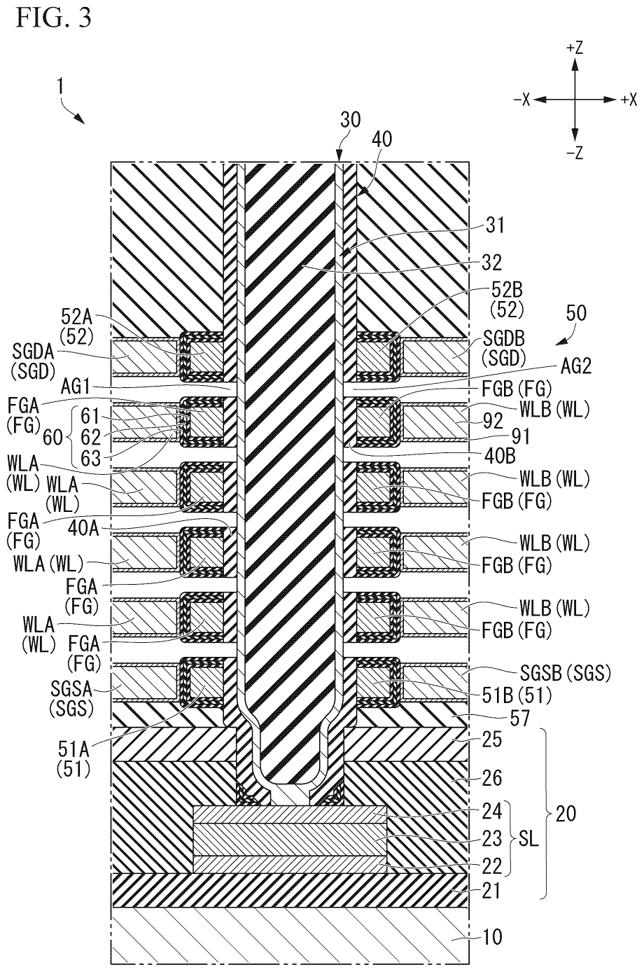

The lower structure 20 is provided on the silicon substrate 10. The lower structure 20 includes, for example, a lower insulating film 21, a plurality of source lines SL, an upper insulating film 25, and an insulating member 26 (refer to FIG. 3). The lower insulating film 21 is provided on the silicon substrate 10. The plurality of source lines SL are provided on the lower insulating film 21. The plurality of source lines SL are adjacent to each other in the X direction and extend in the Y direction. The source line SL is formed of, for example, a conductive layer 22 provided on the lower insulating film 21, an interconnection layer 23 provided on the conductive layer 22, and a conductive layer 24 provided on the interconnection layer 23. The upper insulating film 25 is provided above the plurality of source lines SL. The insulating member 26 is provided between the source line SL and the upper insulating film 25, and between the lower insulating film 21 and the upper insulating film 25.

The plurality of pillars 30 are provided on the source lines SL and extend in the Z direction. The plurality of pillars 30 are provided apart from one another in the X direction and Y direction. For example, the plurality of pillars 30 are disposed in a matrix shape in the X direction and Y direction when viewed from the Z direction. The pillars 30 each include a semiconductor material (for example, amorphous silicon (a-Si)). The pillar 30 may be referred to as a silicon pillar. A lower end of each pillar 30 penetrates the upper insulating film 25 of the lower structure 20 and is connected to the source line SL. A structure of the pillar 30 will be described in detail later.

The plurality of tunnel insulating films 40 are provided at least on a side surface in the −X direction and a side surface in the +X direction of each pillar 30. In the present embodiment, each tunnel insulating film 40 is formed in an annular shape surrounding the side surface in the −X direction, the side surface in the +X direction, a side surface in the −Y direction, and a side surface in the +Y direction of the pillar 30. In the example shown in the drawings, although the plurality of tunnel insulating films 40 are intermittently provided along the side surface in the −X direction and the side surface in the +X direction of each pillar 30, the tunnel insulating films 40 may extend continuously, for example, in the Z direction across an entire length (entire height) of the pillar 30 in the Z direction.

The tunnel insulating film 40 is a film that is normally insulating but allows a tunnel current to flow when a predetermined voltage within a range of a drive voltage of the semiconductor storage device 1 is applied thereto. The tunnel insulating film 40 contains, for example, silicon oxide. Hereinafter, of the tunnel insulating films 40, a portion provided on the side in the −X direction of the pillar 30 is referred to as a “first tunnel insulating film 40A”, and a portion provided on the side in the +X direction of the pillar 30 is referred to as a “second tunnel insulating film 40B”. The first tunnel insulating film 40A is provided between a plurality of first floating gate electrodes FGA disposed in the Z direction, which will be described later, and a first channel portion 31A to be described later. The second tunnel insulating film 40B is provided between a plurality of second floating gate electrodes FGB disposed in the Z direction, which will be described later, and a second channel portion 31B to be described later. The first tunnel insulating film 40A is an example of a “first insulating film”, and the second tunnel insulating film 40B is an example of a “second insulating film”.

The multi-layered body 50 is provided on the lower structure 20. The multi-layered body 50 includes, for example, a plurality of floating gate electrodes FG, a plurality of word lines WL, a plurality of source-side selection gate electrodes 51, a plurality of source-side selection gate lines SGS, a plurality of drain-side selection gate electrodes 52, a plurality of drain-side selection gate lines SGD, a plurality of block insulating films 60, an insulating member 55, and an insulating member 56 (refer to FIG. 34).

The floating gate electrodes FG are each an electrode film provided on a side of the pillar 30. The plurality of floating gate electrodes FG include the plurality of first floating gate electrodes FGA positioned on the side in the −X direction of each pillar 30 and the plurality of second floating gate electrodes FGB positioned on the side in the +X direction thereof. The plurality of first floating gate electrodes FGA are provided apart from each other in the Z direction. The first floating gate electrode FGA is positioned on a side opposite to the pillar 30 with respect to the first tunnel insulating film 40A. Similarly, the plurality of second floating gate electrodes FGB are provided apart from each other in the Z direction. The second floating gate electrode FGB is positioned on a side opposite to the pillar 30 with respect to the second tunnel insulating film 40B. The floating gate electrode FG is a film capable of storing charges. The floating gate electrode FG contains, for example, polysilicon. The first floating gate electrode FGA is an example of a “first charge storage portion”. The second floating gate electrode FGB is an example of a “second charge storage portion”.

The word lines WL are each an interconnection provided on a side of each pillar 30. The plurality of word lines WL include a plurality of first word lines WLA positioned on the side in the −X direction of each pillar 30 and a plurality of second word lines WLB positioned on the side in the +X direction thereof. The first word line WLA is an example of a “first interconnection”. The second word line WLB is an example of a “second interconnection”.

The plurality of first word lines WLA are provided apart from each other in the Z direction. Similarly, the plurality of second word lines WLB are provided apart from each other in the Z direction. The first word line WLA and the second word line WLB are adjacent to each other in the X direction and extend in the Y direction. The first word line WLA is positioned on a side opposite to the first floating gate electrode FGA with respect to the pillar 30. The second word line WLB is positioned on a side opposite to the second floating gate electrode FGB with respect to the pillar 30. In other words, the first floating gate electrode FGA is provided between the first word line WLA and the pillar 30. The second floating gate electrode FGB is provided between the second word line WLB and the pillar 30. The first word line WLA and the second word line WLB are led out, for example, in opposite directions in the Y direction, and are controlled independently of each other.

When electrons are injected into the floating gate electrode FG or when electrons injected into the floating gate electrode FG are removed from the floating gate electrode FG, a voltage is applied to the word line WL by a drive circuit (not shown in the drawings), and a predetermined voltage is applied to the floating gate electrode FG connected to the word line WL. The first floating gate electrode FGA changes a state of electron storage when a voltage is applied by the first word line WLA. On the other hand, the second floating gate electrode FGB changes a state of electron storage when a voltage is applied by the second word line WLB. A configuration of the word line WL will be described in detail later.

The source-side selection gate electrode 51 is an electrode film provided on a side of each pillar 30. The plurality of source-side selection gate electrodes 51 include a first source-side selection gate electrode 51A positioned on the side in the −X direction of each pillar 30 and a second source-side selection gate electrode 51B positioned on the side in the +X direction. The first source-side selection gate electrode 51A is positioned on a side opposite to the pillar 30 with respect to the first tunnel insulating film 40A. The second source-side selection gate electrode 51B is positioned on a side opposite to the pillar 30 with respect to the second tunnel insulating film 40B. The source-side selection gate electrode 51 is provided between the floating gate electrode FG closest to the silicon substrate 10 among the plurality of floating gate electrodes FG corresponding to the same pillar 30 and the silicon substrate 10.

The source-side selection gate line SGS is an interconnection provided on a side of each pillar 30. The plurality of source-side selection gate lines SGS include a first source-side selection gate line SGSA positioned on the side in the −X direction of each pillar 30 and a second source-side selection gate line SGSB positioned on the side in the +X direction thereof. The first source-side selection gate line SGSA is positioned on a side opposite to the pillar 30 with respect to the first source-side selection gate electrode 51A. The second source-side selection gate line SGSB is positioned on a side opposite to the pillar 30 with respect to the second source-side selection gate electrode 51B. The source-side selection gate line SGS extends in the Y direction. When electrical conductivity is provided between the pillar 30 and the source line SL, a voltage is applied to the source-side selection gate line SGS by a drive circuit (not shown in the drawings), and a predetermined voltage is applied to the source-side selection gate electrode 51 connected to the source-side selection gate line SGS. The source-side selection gate line SGS is positioned between the word line WL closest to the silicon substrate 10 among the plurality of word lines WL corresponding to the same pillar 30 and the silicon substrate 10. In the present embodiment, the source-side selection gate line SGS and the source-side selection gate electrode 51 are collectively referred to as a selection transistor. Note that, the selection transistor may not include the source-side selection gate electrode 51.

The drain-side selection gate electrode 52 is an electrode film provided on a side of each pillar 30. The plurality of drain-side selection gate electrodes 52 include a first drain-side selection gate electrode 52A positioned on the side in the −X direction of each pillar 30 and a second drain-side selection gate electrode 52B positioned on the side in the +X direction thereof. The first drain-side selection gate electrode 52A is positioned on a side opposite to the pillar 30 with respect to the first tunnel insulating film 40A. The second drain-side selection gate electrode 52B is positioned on a side opposite to the pillar 30 with respect to the second tunnel insulating film 40B. The drain-side selection gate electrode 52 is positioned farther from the silicon substrate 10 than the floating gate electrode FG farthest from the silicon substrate 10 among the plurality of floating gate electrodes FG corresponding to the same pillar 30.

The drain-side selection gate line SGD is an interconnection provided on a side of each pillar 30. The plurality of drain-side selection gate lines SGD include a first drain-side selection gate line SGDA positioned on the side in the −X direction of each pillar 30 and a second drain-side selection gate line SGDB positioned on the side in the +X direction thereof. The first drain-side selection gate line SGDA is positioned on a side opposite to the pillar 30 with respect to the first drain-side selection gate electrode 52A. The second drain-side selection gate line SGDB is positioned on a side opposite to the pillar 30 with respect to the second drain-side selection gate electrode 52B. The drain-side selection gate line SGD extends in the Y direction. When electrical conductivity is provided between the pillar 30 and the bit line BL to be described later, a voltage is applied to the drain-side selection gate line SGD by a drive circuit (not shown in the drawings), and a predetermined voltage is applied to the drain-side selection gate electrode 52 connected to the drain-side selection gate line SGD. The drain-side selection gate line SGD is positioned farther from the silicon substrate 10 than the word line WL farthest from the silicon substrate 10 among the plurality of word lines WL corresponding to the same pillar 30. That is, the drain-side selection gate line SGD is positioned on a side opposite to the silicon substrate 10 with respect to the plurality of word lines WL corresponding to the same pillar 30.

In the present embodiment, the drain-side selection gate line SGD and the drain-side selection gate electrode 52 are collectively referred to as a selection transistor. Note that, the selection transistor may not include the drain-side selection gate electrode 52.

The block insulating film 60 is provided between the floating gate electrode FG and the word line WL, between the source-side selection gate electrode 51 and the source-side selection gate line SGS, and between the drain-side selection gate electrode 52 and the drain-side selection gate line SGD. The block insulating film 60 is a film that does not substantially allow a current to flow even when a voltage within a range of the drive voltage of the semiconductor storage device 1 is applied. A configuration of the block insulating film 60 will be described in detail later.

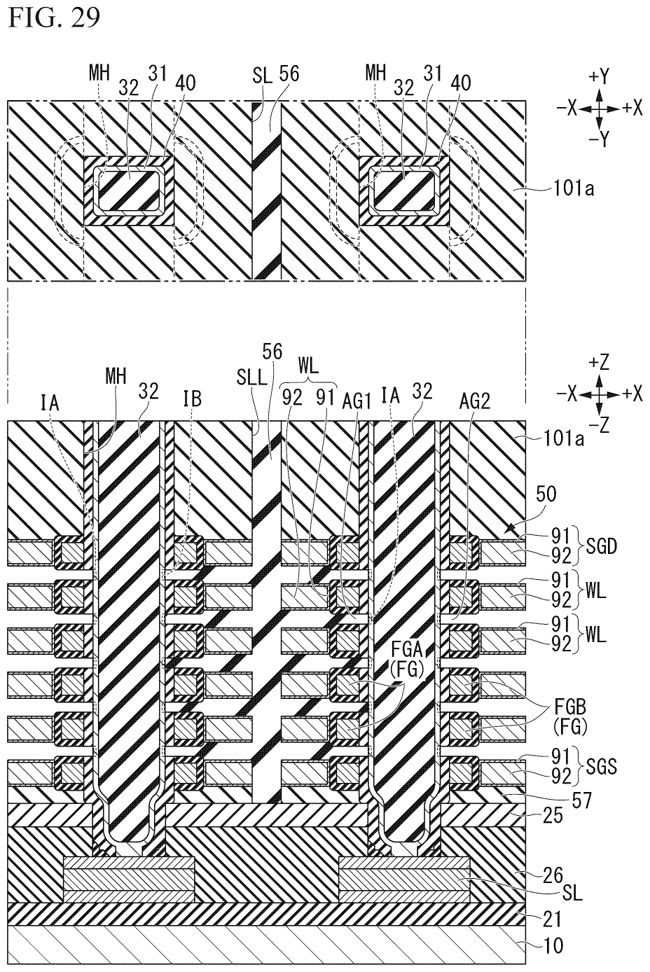

The insulating member 55 is provided between the pillars 30 disposed in the Y direction, and thereby electrical insulation is provided between the plurality of pillars 30. In other words, the word line WL and the floating gate electrode FG are not provided between two pillars 30 disposed in the Y direction. Therefore, the first floating gate electrode FGA and the second floating gate electrode FGB are not connected to each other. Also, the insulating member 56 (refer to FIG. 29) is provided between the word lines WL adjacent to each other in the X direction, and thereby electrical insulation is provided between the plurality of word lines WL.

The upper structure 70 is provided on the multi-layered body 50. The upper structure 70 includes, for example, a plurality of bit lines BL, an interconnection L1 (not shown in the drawings) for the source-side selection gate line SGS, an interconnection L2 for the word line WL, and an interconnection L3 for the drain-side selection gate line SGD.

The plurality of contacts 80 each extend in the Z direction. The plurality of contacts 80 include, for example, a plurality of contacts 81 for the pillars 30, a plurality of contacts 82 (not shown in the drawings) for the source-side selection gate lines SGS, a plurality of contacts 83 for the word lines WL, and a plurality of contacts 84 for the drain-side selection gate lines SGD.

The contact 81 is provided on the pillar 30. The plurality of bit lines BL are provided apart from each other in the Y direction and extend in the X direction. Of the plurality of pillars 30 disposed in the X direction, if the pillar 30 positioned furthest on the side in the −X direction is defined as a first pillar, odd-numbered pillars 30A are connected to a common bit line BLA via the contacts 81. Even-numbered pillars 30B are connected to a common bit line BLB separate from the bit line BLA via the contacts 81. Among the plurality of pillars 30 disposed in the X direction, adjacent pillars 30A and 30B are not connected to a common bit line.

The plurality of contacts 82 (not shown in the drawings) are each provided on an end part of the source-side selection gate line SGS in the +Y direction. The interconnection L1 (not shown in the drawings) is provided on the contact 82 and extends in the Y direction. The interconnection L1 is connected to the source-side selection gate line SGS via the contact 82.

The plurality of contacts 83 are each provided on an end part of the word line WL in the Y direction. The interconnection L2 is provided on the contact 83 and extends in the Y direction. The interconnection L2 is connected to the word line WL via the contact 83.

The plurality of contacts 84 are each provided on an end part of the drain-side selection gate line SGD in the +Y direction. The interconnection L3 is provided on the contact 84 and extends in the Y direction. The interconnection L3 is connected to the drain-side selection gate line SGD via the contact 84.

### 2. Configurations of Multi-Layered Body, Word Line, and Pillar

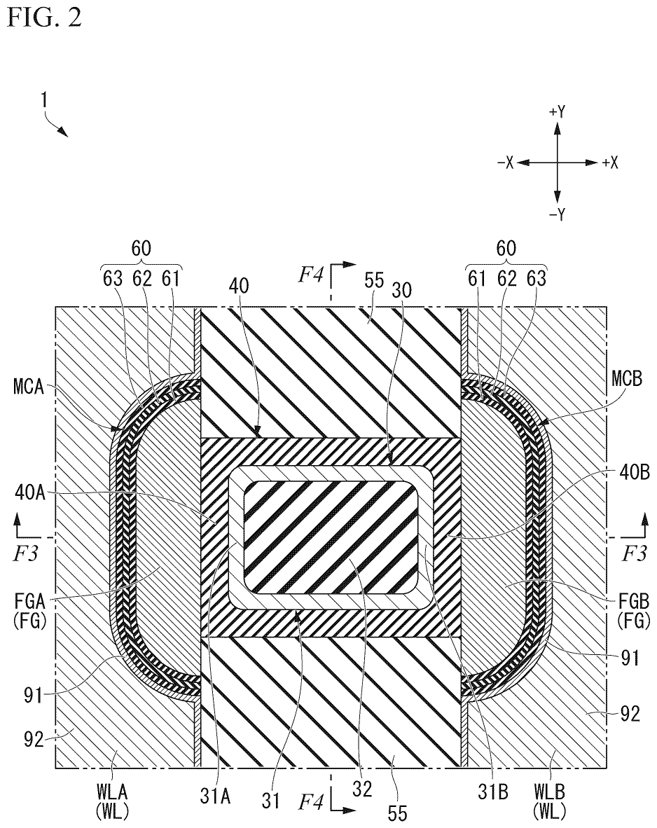

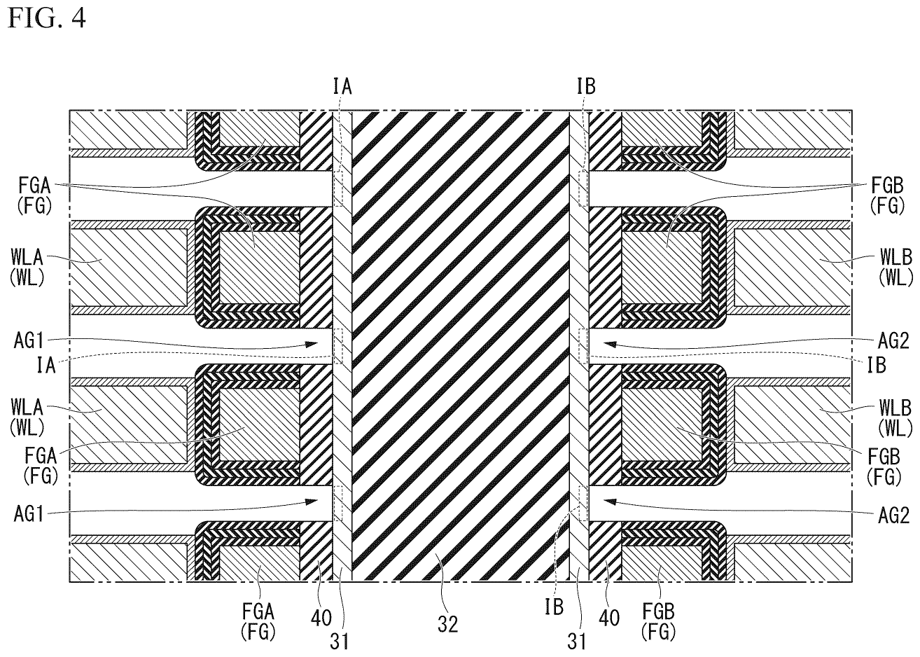

Next, configurations of the multi-layered body 50, the word line WL, and the pillar 30 of the present embodiment will be described in detail. FIG. 2 is a cross-sectional view, including the word line WL, of a region surrounded by a two-dot chain line F2 of the semiconductor storage device 1 shown in FIG. 1 from the Z direction. FIG. 3 is a cross-sectional view of the semiconductor storage device 1 shown in FIG. 2 along line F3-F3. FIG. 4 is an enlarged cross-sectional view showing the first floating gate electrode FGA shown in FIG. 2 and a vicinity thereof. Note that, from FIG. 2 onward, only four word lines WL disposed in the Z direction are shown for convenience of explanation.

### 2.1 Floating Gate Electrode

First, the plurality of floating gate electrodes FG will be described.

As shown in FIGS. 2 and 3, the plurality of first floating gate electrodes FGA are each positioned between the first word line WLA and the pillar 30. On the other hand, the plurality of second floating gate electrodes FGB are each positioned between the second word line WLB and the pillar 30. In the present embodiment, the plurality of floating gate electrodes FG are each formed in a trapezoidal shape with end parts in the −Y and +Y directions being arcuate.

Among the plurality of first floating gate electrodes FGA, the first floating gate electrodes FGA adjacent to each other in the Z direction are provided so that a first gap AG1 is formed between the first floating gate electrodes FGA. Also, among the plurality of second floating gate electrodes FGB, the second floating gate electrodes FGB adjacent to each other in the Z direction are provided so that a second gap AG2 is formed between the second floating gate electrodes FGB. This configuration can also be expressed as follows. That is, the first gap AG1 is provided between the first floating gate electrodes FGA adjacent to each other in the Z direction. Also, the second gap AG2 is provided between the second floating gate electrodes FGB adjacent to each other in the Z direction, thereby exposing a part of a channel portion 31 (specifically, a first impurity diffusion region IA and a second impurity diffusion region IB). However, in a case of a form in which the first tunnel insulating film 40A and the second tunnel insulating film 40B to be described later extend continuously in the Z direction over the entire length (entire height) of the pillar 30 in the Z direction, the first tunnel insulating film 40A and the second tunnel insulating film 40B are exposed by the first gap AG1 and the second gap AG2.

The first gap AG1 and the second gap AG2 only need to be respectively provided between the first floating gate electrodes FGA adjacent to each other in the Z direction and between the second floating gate electrodes FGB adjacent to each other in the Z direction, and lengths of the first gap AGI and the second gap AG2 in the X direction are not particularly limited. For example, the first gap AGI and the second gap AG2 may extend in the X direction to a position of the word line WL. In other words, the word lines WL adjacent to each other in the Z direction may be provided such that the first gap AG1 or the second gap AG2 is formed between the word lines WL.

### 2.2 Word Lines

Next, the word lines WL will be described.

The word line WL includes, for example, a barrier metal film 91 and a conductive member 92. The barrier metal film 91 is provided on a surface of the word line WL. The barrier metal film 91 is a film that suppresses diffusion of a material of the conductive member 92. The barrier metal film 91 contains, for example, titanium nitride (TiN). The conductive member 92 is provided inside the barrier metal film 91. The conductive member 92 contains, for example, tungsten.

### 2.3 Block Insulating Film

Next, the block insulating film 60 will be described.

The block insulating film 60 is provided, for example, between the first floating gate electrode FGA and the first word line WLA, and between the second floating gate electrode FGB and the second word line WLB. The block insulating film 60 includes, for example, a first block insulating film 61, a second block insulating film 62, and a third block insulating film 63.

Of the first block insulating film 61, the second block insulating film 62, and the third block insulating film 63, the first block insulating film 61 is positioned closest to the floating gate electrode FG. The first block insulating film 61 covers, for example, a side surface, an upper surface, and a lower surface of the floating gate electrode FG. The first block insulating film 61 contains a high-k material such as, for example, silicon nitride (SiN) and hafnium oxide (HfO). Note that, the first block insulating film 61 may be formed of a material containing ruthenium (Ru), aluminum (Al), titanium (Ti), zirconium (Zr), or silicon (Si).

The second block insulating film 62 is provided on a side opposite to the floating gate electrode FG with respect to the first block insulating film 61. The second block insulating film 62 covers, for example, the side surface, the upper surface, and the lower surface of the floating gate electrode FG via the first block insulating film 61. Note that, instead of the above configuration, the second block insulating film 62 may cover only the side surface of the floating gate electrode FG and be provided along a surface of the word line WL. The second block insulating film 62 contains, for example, silicon oxide.

The third block insulating film 63 is provided on a side opposite to the floating gate electrode FG with respect to the first block insulating film 61 and the second block insulating film 62. The third block insulating film 63 covers, for example, the side surface, the upper surface, and the lower surface of the floating gate electrode FG via the first block insulating film 61 and the second block insulating film 62. Note that, instead of the above configuration, the third block insulating film 63 may cover only the side surface of the floating gate electrode FG and be provided along the surface of the word line WL. The third block insulating film 63 only need to be formed of a material with a high dielectric constant and may be formed of a high-k film of an oxide film containing, for example, aluminum (Al), hafnium (Hf), or zirconium (Zr). Note that, the third block insulating film 63 may be formed of silicon nitride.

### 2.4 Tunnel Insulating Film

Next, the tunnel insulating film 40 will be described.

The plurality of first tunnel insulating films 40A are each positioned between the first floating gate electrode FGA and the pillar 30. The plurality of second tunnel insulating films 40B are each positioned between the second floating gate electrode FGB and the pillar 30. In the present embodiment, a “first memory film (first memory cell) MCA” is formed of the first floating gate electrode FGA, the block insulating film 60, and the first tunnel insulating film 40A. On the other hand, a “second memory film (second memory cell) MCB” is formed of the second floating gate electrode FGB, the block insulating film 60, and the second tunnel insulating film 40B.

The plurality of first tunnel insulating films 40A are provided intermittently along a side surface of each pillar 30 in the −X direction. The plurality of second tunnel insulating films 40B are provided intermittently along a side surface of each pillar 30 in the +X direction. Note that, the plurality of first tunnel insulating films 40A and the plurality of second tunnel insulating films 40B may all extend continuously in the Z direction, for example, over the entire length (entire height) of the pillar 30 in the Z direction.

### 2.5 Pillar

Next, the pillar 30 will be described.

The pillar 30 is provided between the first word line WLA and the second word line WLB in the X direction. The pillar 30 includes an insulating core 32 and the channel portion 31 in order from an inner circumferential side thereof. The channel portion 31 includes the first impurity diffusion region IA and the second impurity diffusion region IB in which an impurity element is diffused.

The insulating core 32 extends in the Z direction and has a columnar shape. The insulating core 32 is provided on a center side of the pillar 30 relative to the channel portion 31 in the X direction and Y direction. For example, the insulating film 32 is provided on an inner circumferential surface of the channel portion 31. The insulating core 32 contains, for example, silicon oxide. The insulating core 32 is provided at a central portion including a central axis of the pillar 30 when viewed from the Z direction.

The channel portion 31 is positioned on a outermost circumference of the pillar 30. The channel portion 31 extends in the Z direction over the entire length (entire height) of the pillar 30 in the Z direction, and is formed, for example, in an annular shape. The channel portion 31 covers an outer surface (outer circumferential surface) of the insulating core 32. The channel portion 31 contains, for example, silicon. The silicon is, for example, polysilicon obtained by crystallizing amorphous silicon. A lower end of the channel portion 31 penetrates the upper insulating film 25 of the lower structure 20 and is connected to the source line SL. On the other hand, an upper end of the channel portion 31 is connected to the bit line BL via the contact 81. When electrons are injected into the floating gate electrode FG and when electrons injected into the floating gate electrode FG are removed from the floating gate electrode FG, the channel portion 31 functions as a carrier flow path (a so-called “channel”) between the source line SL and the bit line BL. The channel portion 31 may be referred to as a “semiconductor layer” or a “silicon layer”.

The channel portion 31 includes the first channel portion 31A positioned on the side in the −X direction of the channel portion 31, and the second channel portion 31B positioned on the side in the +X direction of the channel portion 31. The first channel portion 31A is provided between the first word line WLA and the second word line WLB, and extends in the Z direction. The first channel portion 31A faces the first source-side selection gate electrode 51A, the plurality of first floating gate electrodes FGA, and the first drain-side selection gate electrode 52A with the first tunnel insulating film 40A interposed therebetween. The second channel portion 31B is provided between the first word line WLA and the second word line WLB, is adjacent to the first channel portion 31A in the X direction, and extends in the Z direction. The second channel portion 31B faces the second source-side selection gate electrode 51B, the plurality of second floating gate electrodes FGB, and the second drain-side selection gate electrode 52B with the second tunnel insulating film 40B interposed therebetween. In the present embodiment, the channel portion 31 is formed in an annular shape.

The first channel portion 31A includes the first impurity diffusion region IA in which an impurity element is diffused thereinside. The first impurity diffusion region IA is provided inside the first channel portion 31A at least between the first floating gate electrodes FGA adjacent to each other in the Z direction. The first impurity diffusion region IA is formed by at least part of the channel portion 31 doped with impurities. Therefore, the first impurity diffusion region IA is exposed on an outer surface of the first channel portion 31A. The first impurity diffusion region IA is a region doped with an n-type impurity element (for example, phosphorus (P), arsenic (As), antimony (Sb), or the like) from the side of the first gap AGI into the first channel portion 31A. The first impurity diffusion region IA may contain two or more types of elements.

The second channel portion 31B includes the second impurity diffusion region TB in which an impurity element is diffused inside the second channel portion 31B. The second impurity diffusion region IB is provided inside the second channel portion 31B at least between the second floating gate electrodes FGB adjacent to each other in the Z direction. The second impurity diffusion region IB is formed by at least part of the channel portion 31 doped with impurities. Therefore, the second impurity diffusion region IB is exposed on an outer surface of the second channel portion 31B. The second impurity diffusion region IB is a region doped with an n-type impurity element (for example, phosphorus (P), arsenic (As), antimony (Sb), or the like) from the side of the second gap AG2 into the first channel portion 31B. The second impurity diffusion region IB may contain two or more types of elements. The element contained in the first impurity diffusion region IA and the element contained in the second impurity diffusion region IB may be different or the same.

A length of the first impurity diffusion region IA in the Z direction may be larger than a distance between the first memory cells MCA adjacent to each other in the Z direction, that is, a distance between the block insulating films 60 adjacent to each other in the Z direction. Therefore, better suppression of a decrease in cell current can be achieved. The length of the first impurity diffusion region IA in the Z direction may be larger than a distance between the first floating gate electrodes FGA adjacent to each other in the Z direction. Therefore, a decrease in cell current can be further suppressed.

A length of the second impurity diffusion region IB in the Z direction may be larger than a distance between the second memory cells MCB adjacent to each other in the Z direction, that is, a distance between the block insulating films 60 adjacent to each other in the Z direction. Therefore, better suppression of a decrease in cell current can be achieved. The length of the second impurity diffusion region IB in the Z direction may be larger than a distance between the second floating gate electrodes FGB adjacent to each other in the Z direction. Therefore, a decrease in cell current can be further suppressed.

Thicknesses of the first impurity diffusion region IA and the second impurity diffusion region IG in the X direction may each be larger than or equal to half a thickness of the channel portion 31 in the X direction. From the perspective of suppressing a decrease in cell current, the thickness of each of the first impurity diffusion region and the second impurity diffusion region in the X direction may be the same as the thickness of the channel portion 31 in the X direction.

Note that, a planar layout and a cross-sectional layout of the semiconductor storage device 1 are not limited to those shown in FIGS. 1 to 3, and other layouts may also be used. For example, the number and disposition of the pillars 30, the number of word lines WL, or the like can be changed as appropriate.

### 3. Function

As described above, in the semiconductor storage device 1 of the present embodiment, the first floating gate electrodes FGA adjacent to each other in the Z direction are provided to form the first gap AG1. Similarly, the second floating gate electrodes FGB adjacent to each other in the Z direction are provided to form the second gap AG2. Therefore, it is possible to reduce electric field interference between memory cells (for example, between the first memory cells MCA adjacent to each other) compared to a conventional case in which an insulator formed of, for example, silicon oxide is provided between the first floating gate electrodes FGA or between the second floating gate electrodes FGB. However, simply providing a gap between the floating gate electrodes FG may result in a decrease in cell current due to a decrease in fringe field effect compared to the case in which the conventional insulator is provided. Therefore, in the present embodiment, a decrease in cell current can be suppressed by forming the first impurity diffusion region IA and the second impurity diffusion region IG inside the channel portion 31 positioned between the floating gate electrodes FG.

### 4. Manufacturing Method of Semiconductor Storage Device

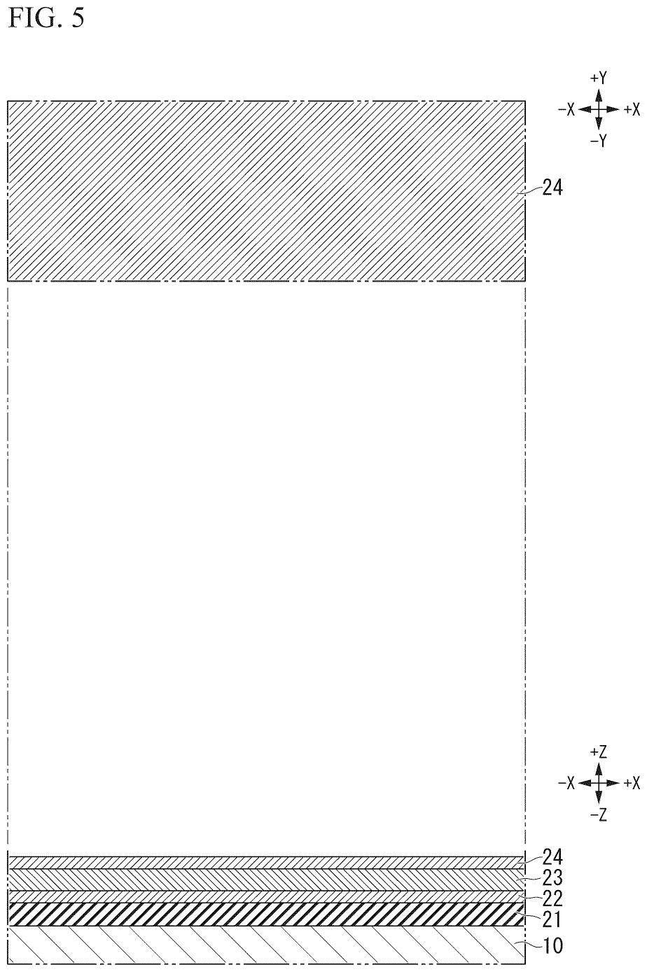

Next, an example of a manufacturing method of the semiconductor storage device 1 will be described. FIGS. 5 to 29 are views showing a manufacturing method of the semiconductor storage device 1.

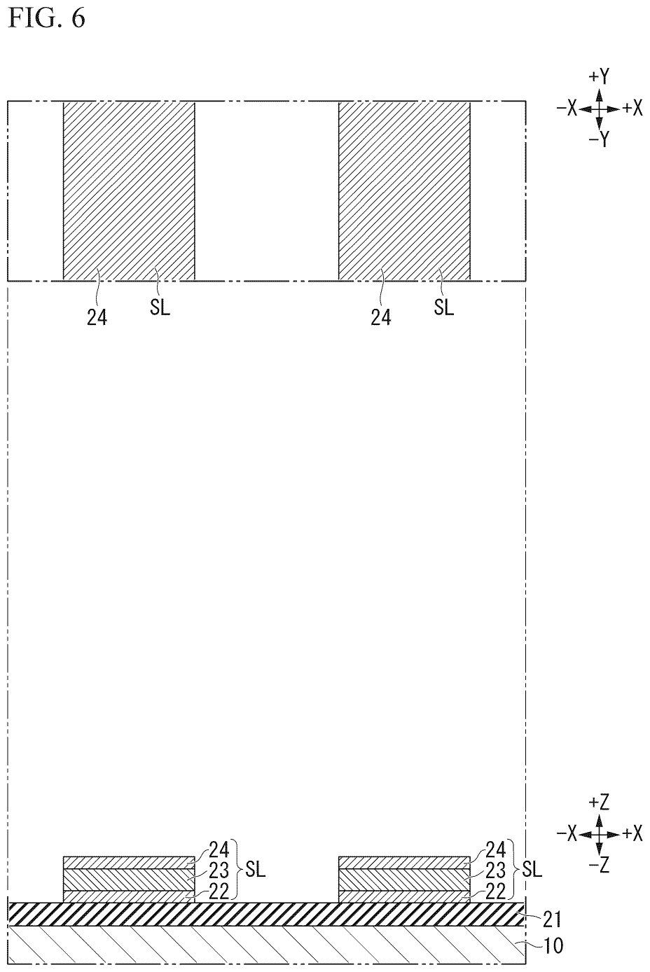

First, as shown in FIG. 5, the lower insulating film 21, the conductive layer 22, the interconnection layer 23, and the conductive layer 24 are formed on the silicon substrate 10. Next, as shown in FIG. 6, for example, dry etching is performed to selectively remove the conductive layer 22, the interconnection layer 23, and the conductive layer 24. Therefore, the source line SL is formed.

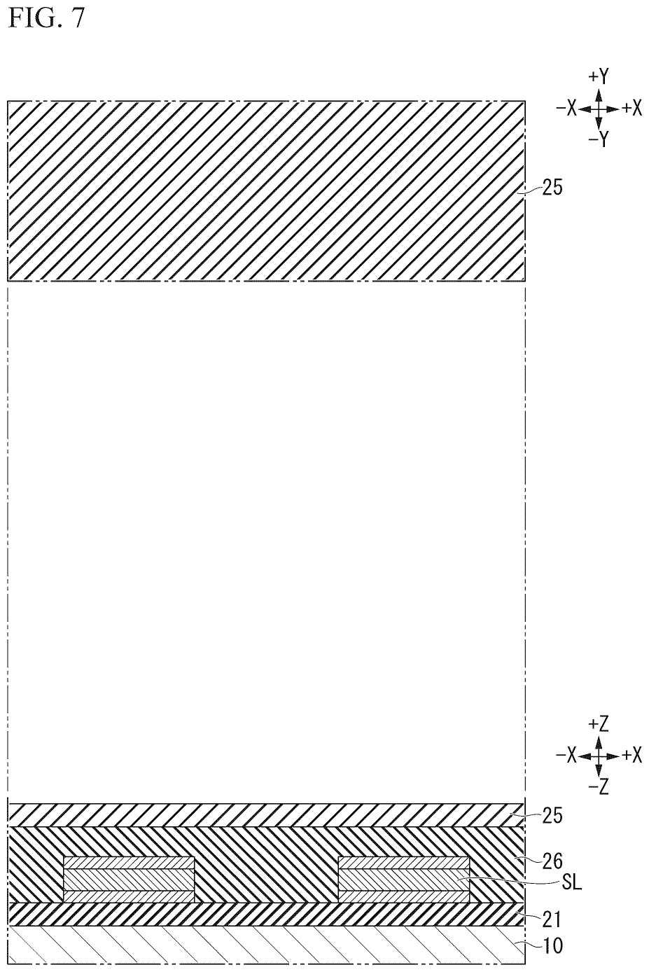

Next, as shown in FIG. 7, the insulating member 26 and the upper insulating film 25 are formed on the lower insulating film 21 and the source line SL. A material of the insulating member 26 is, for example, silicon oxide. A material of the upper insulating film 25 is, for example, silicon oxide.

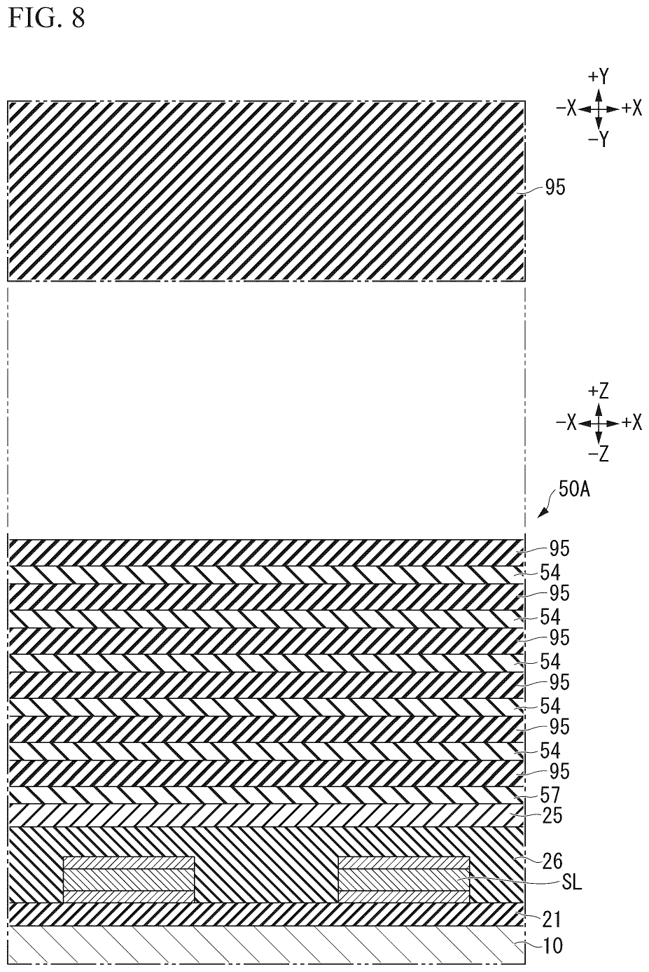

Next, as shown in FIG. 8, an insulating film 57 containing, for example, silicon oxide is formed on the upper insulating film 25. Next, for example, a first filling film 95 containing silicon nitride and a second filling film 54 containing polysilicon are alternately stacked on the insulating film 57 by a chemical vapor deposition (CVD) method to form a intermediate-multi-layered body 50A.

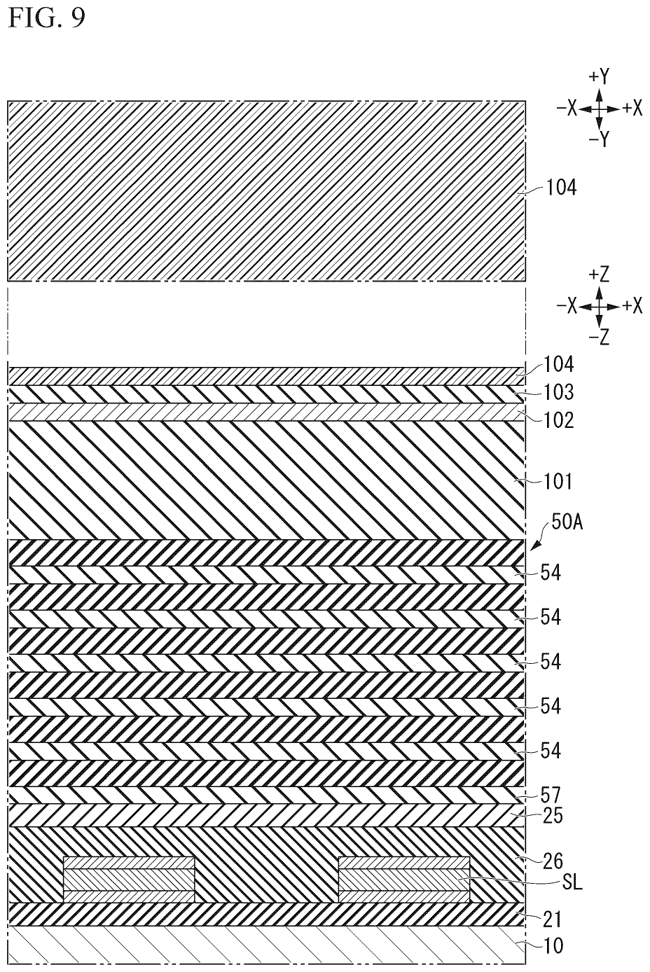

Next, as shown in FIG. 9, for example, silicon oxide (SiO₂) is deposited on the intermediate-multi-layered body 50A to form a mask 101. Next, a pattern film 102 containing, for example, carbon (C), an anti-reflective coating (ARC) 103, and a resist film 104 are formed on the mask 101.

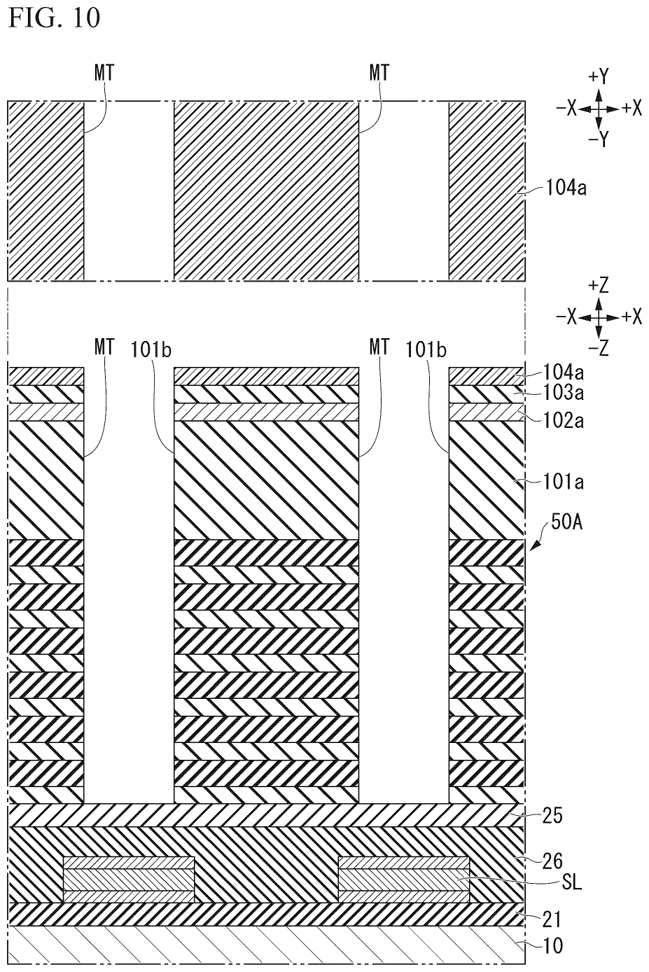

Next, as shown in FIG. 10, the resist film 104 is exposed and developed to form a resist pattern 104a. Next, etching is performed to form an anti-reflective coating 103a and a pattern film 102a. Next, the mask 101 is patterned to form a mask 101a. Therefore, the mask 101a has an opening 101b extending in the Y direction. Next, using the mask 101a as a mask, for example, wet etching is performed to penetrate the intermediate-multi-layered body 50A in the Z direction, thereby forming a memory cell trench MT that reaches the upper insulating film 25.

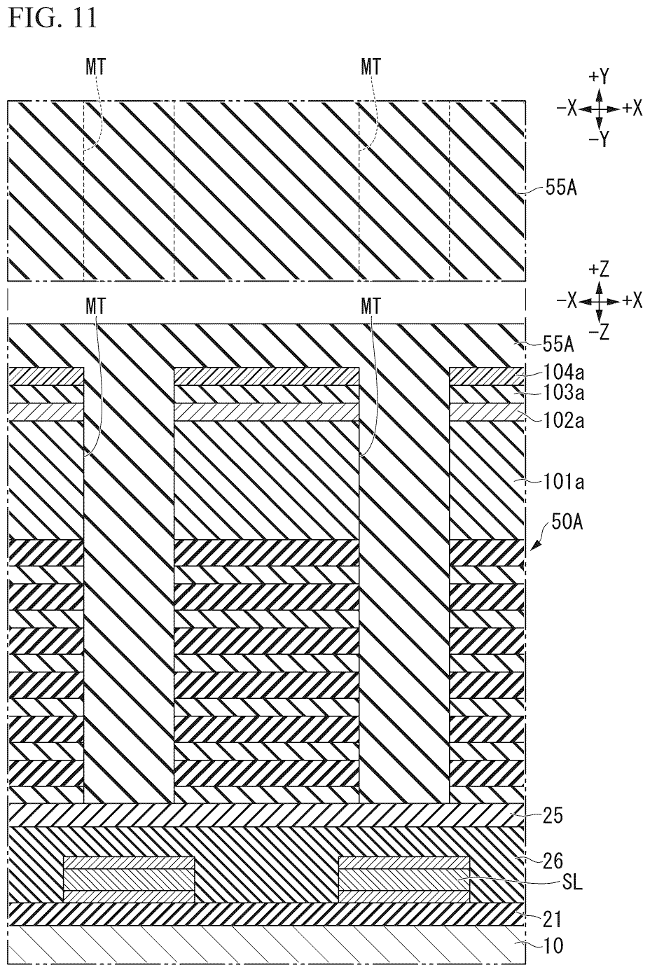

Next, as shown in FIG. 11, an insulating material such as silicon oxide is deposited in the memory cell trench MT and on the resist pattern 104a. Therefore, an insulating film 55A that serves as a base for the insulating member 55 is formed inside the memory cell trench MT.

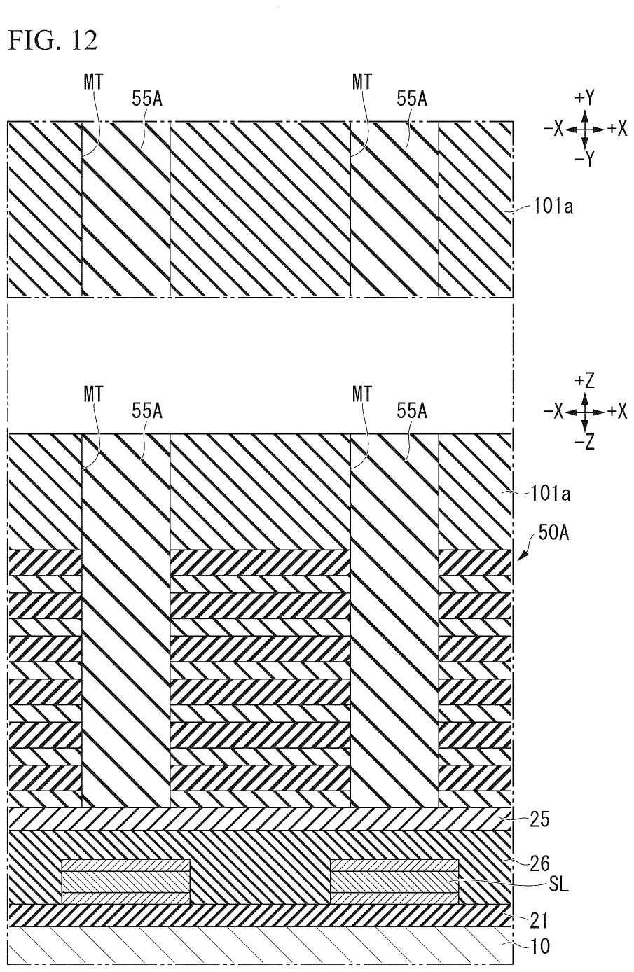

Next, as shown in FIG. 12, an unnecessary portion of the insulating film 55A positioned above the resist pattern 104a are removed by, for example, etch-back. Subsequently, the resist pattern 104a, the anti-reflective coating 103a, and the pattern film 102a are removed.

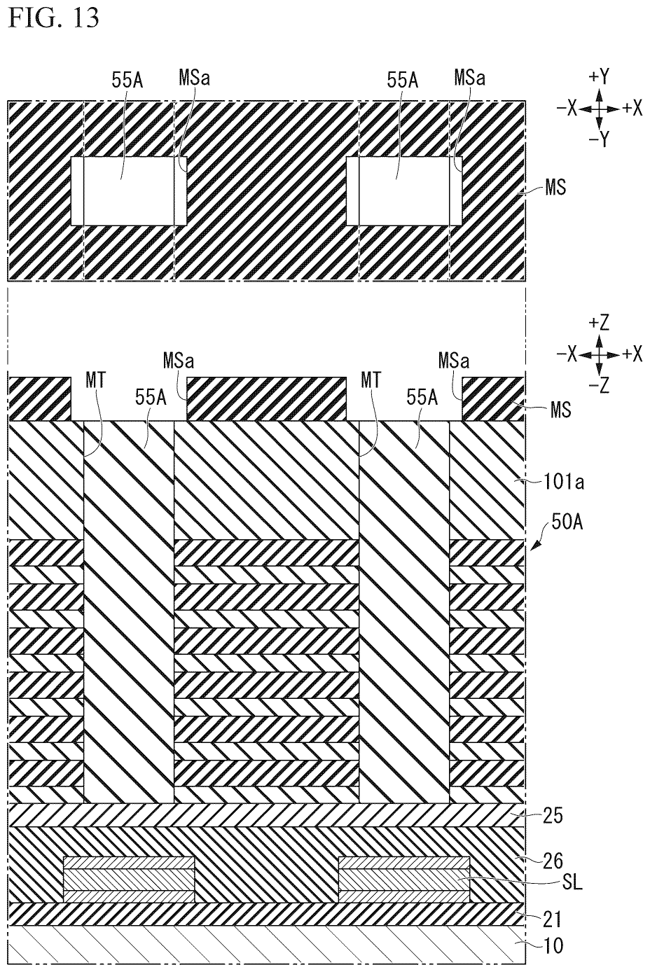

Next, as shown in FIG. 13, for example, a hard mask MS is provided on, for example, the mask 101a. The hard mask MS has an opening MSa at a position corresponding to a memory hole MH to be described later.

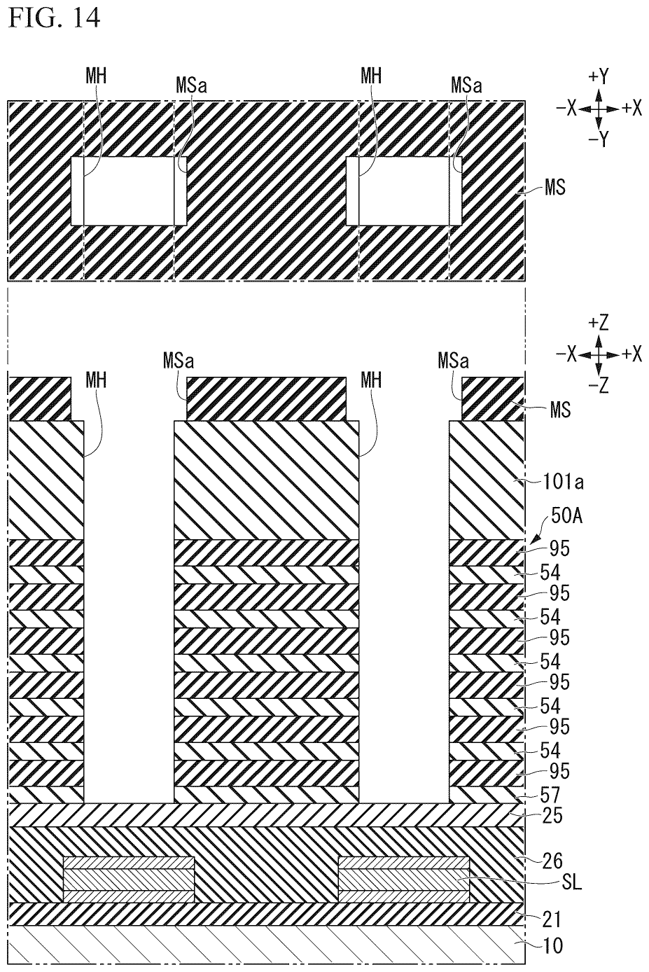

Next, as shown in FIG. 14, using the hard mask MS as a mask, for example, wet etching is performed to remove a portion of the intermediate-multi-layered body 50A exposed to the opening MSa of the hard mask MS. Here, in the present embodiment, an etchant that allows the mask 101a below the hard mask MS to remain without being removed is used. Therefore, the insulating film 57, the first filling film 95, and the second filling film 54 are not removed, and only an unnecessary portion of the insulating film 55A is removed.

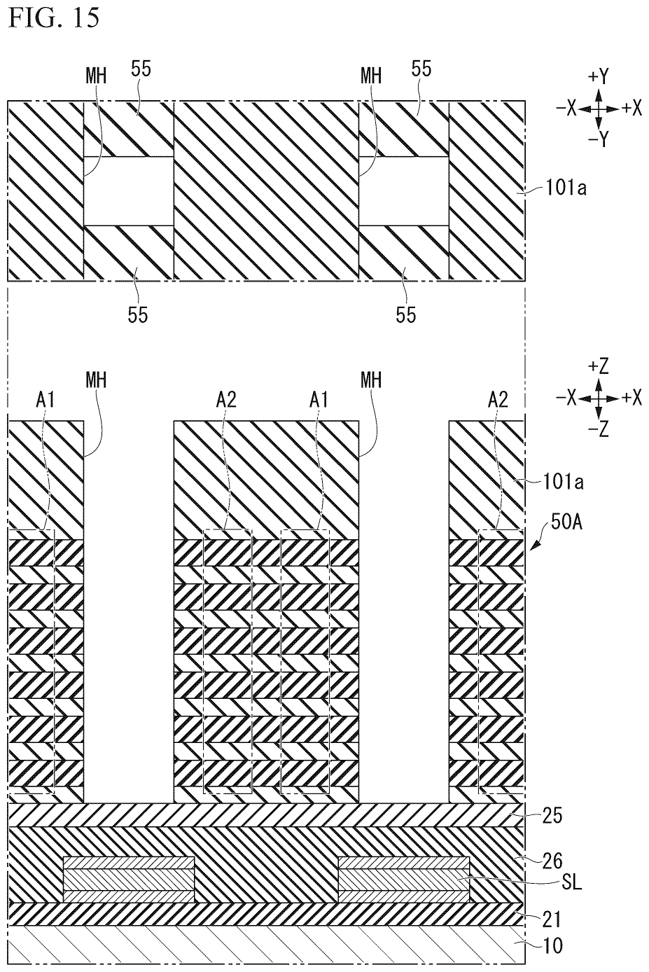

Therefore, as shown in FIG. 15, the memory hole MH penetrating the insulating film 55A in the Z direction is formed, and a remaining portion of the insulating film 55A becomes the insulating member 55. The memory hole MH is provided in the intermediate-multi-layered body 50A between a first interconnection region A1 and a second interconnection region A2. The “interconnection region” may be a region in which an interconnection has already been formed, or a region in which an interconnection will be formed in a later process. In the present embodiment, the first interconnection region A1 is a region in which the first word line WLA is formed in a later process, and the second interconnection region A2 is a region in which the second word line WLB is formed in a later process.

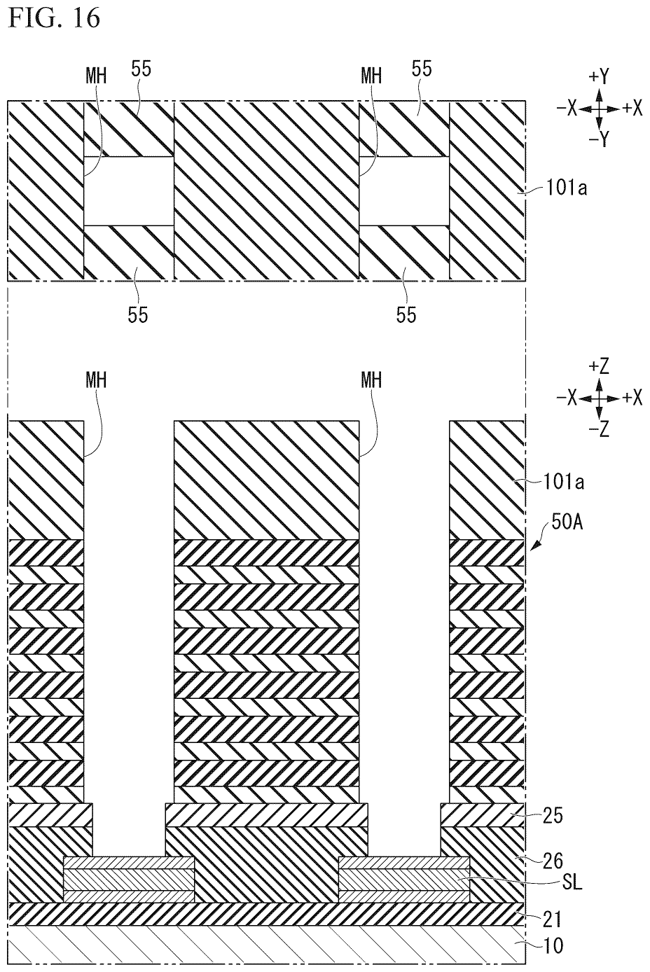

Next, as shown in FIG. 16, a portion of the upper insulating film 25 exposed to the memory hole MH is removed by, for example, etching to expose the source line SL.

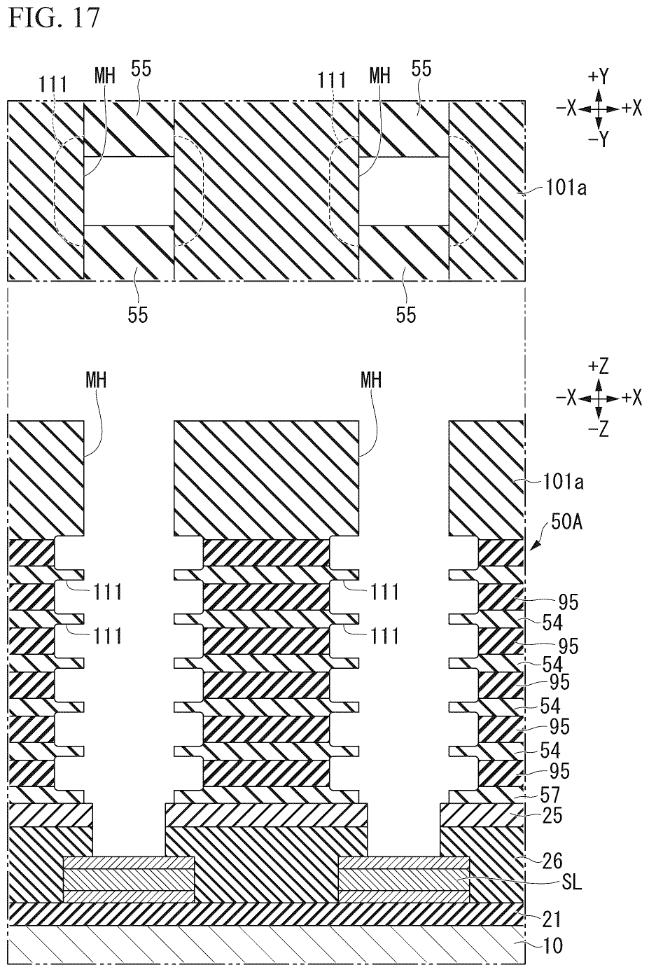

Next, as shown in FIG. 17, wet etching is performed through the memory hole MH using, for example, hot phosphoric acid (H₃PO₄), which is a chemical solution that dissolves silicon nitride, as an etchant. Therefore, a portion of the first filling film 95 on the side on the memory hole MH is removed, and a recess 111 is formed on a side surface of the memory hole MH.

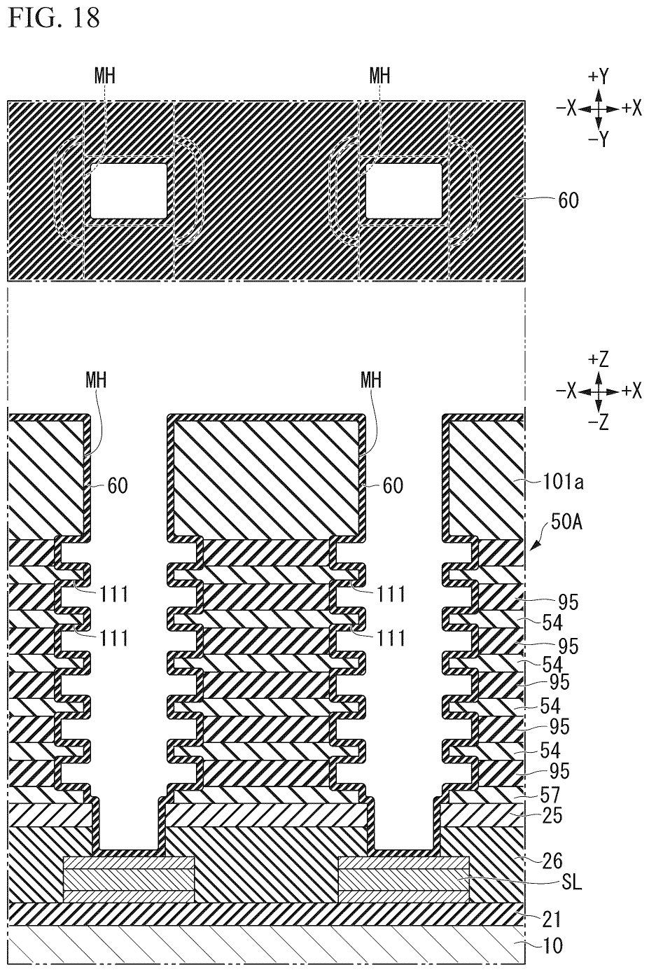

Next, as shown in FIG. 18, for example, an insulating material is deposited on an inner surface of the memory hole MH and an inner surface of the recess 111 to form the block insulating film 60.

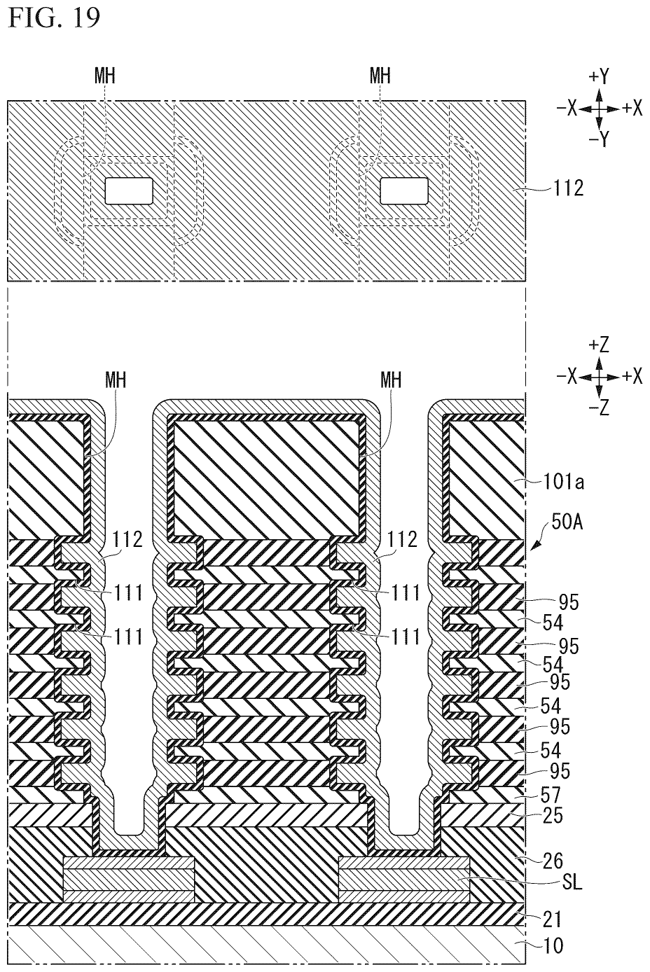

Next, as shown in FIG. 19, for example, polysilicon is deposited on an inner circumferential surface of the block insulating film 60 to form a floating gate electrode film 112. At this time, the polysilicon is provided such that the recess 111 is filled therewith.

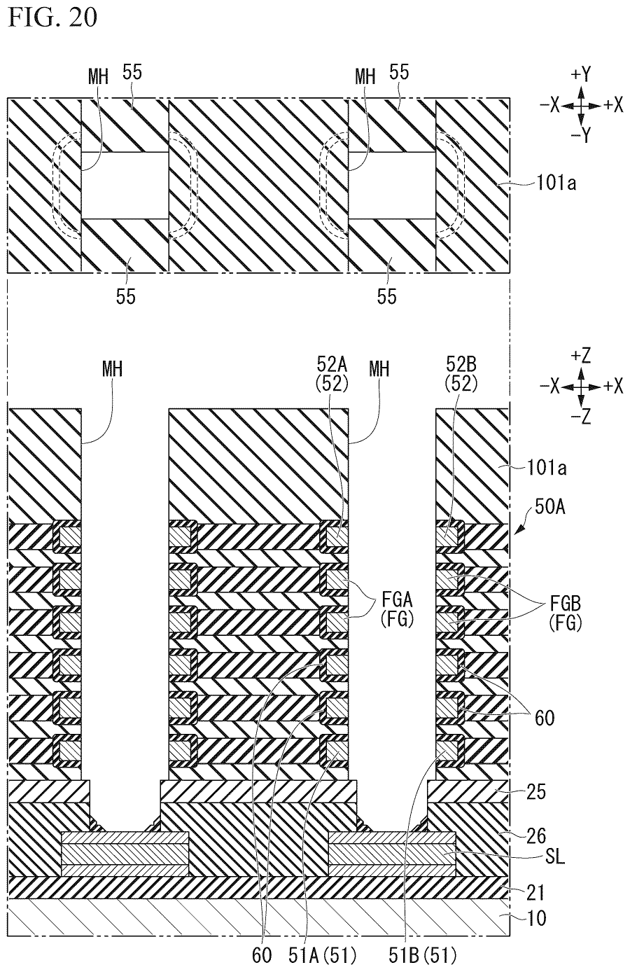

Next, as shown in FIG. 20, an unnecessary insulating material and polysilicon are removed from an inner surface of the memory hole MH. Therefore, an unnecessary portion of the floating gate electrode film 112 is removed, thereby forming the floating gate electrode FG.

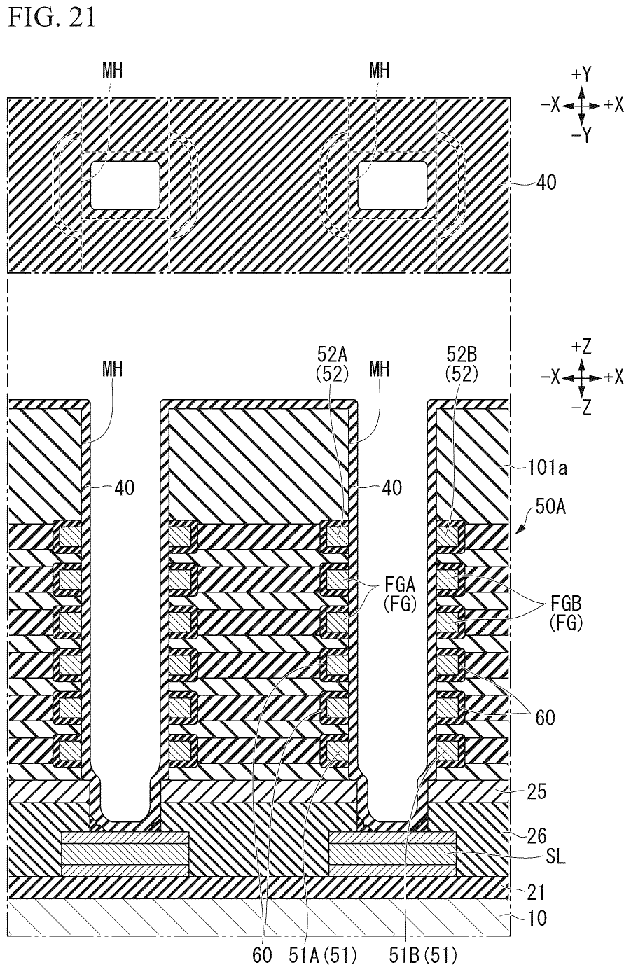

Next, as shown in FIG. 21, for example, silicon oxide is deposited on an inner surface of the memory hole MH to form the tunnel insulating film 40.

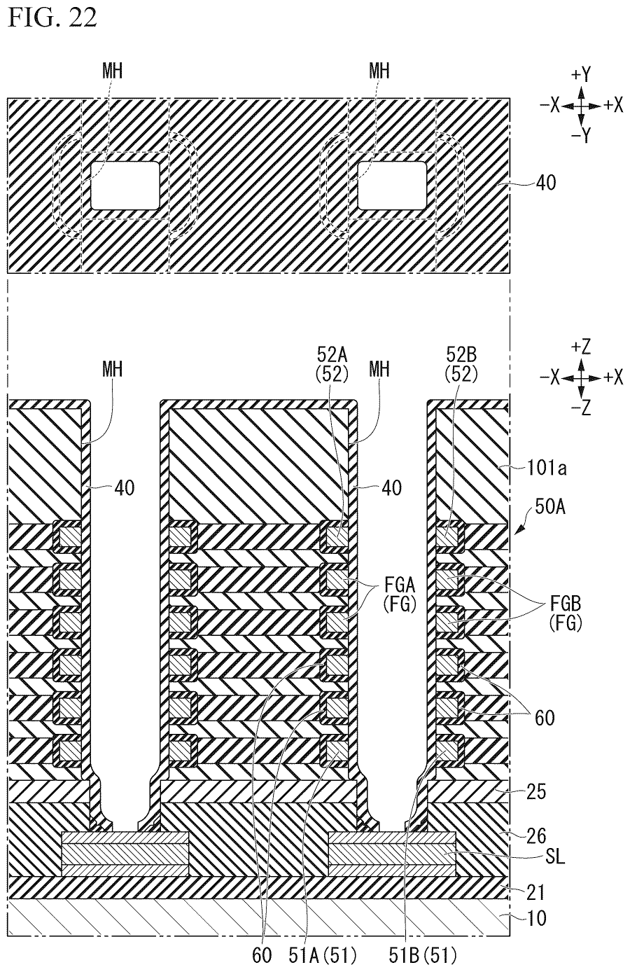

Next, as shown in FIG. 22, for example, etching is performed to remove a bottom part of the tunnel insulating film 40, thereby exposing the source line SL to the memory hole MH.

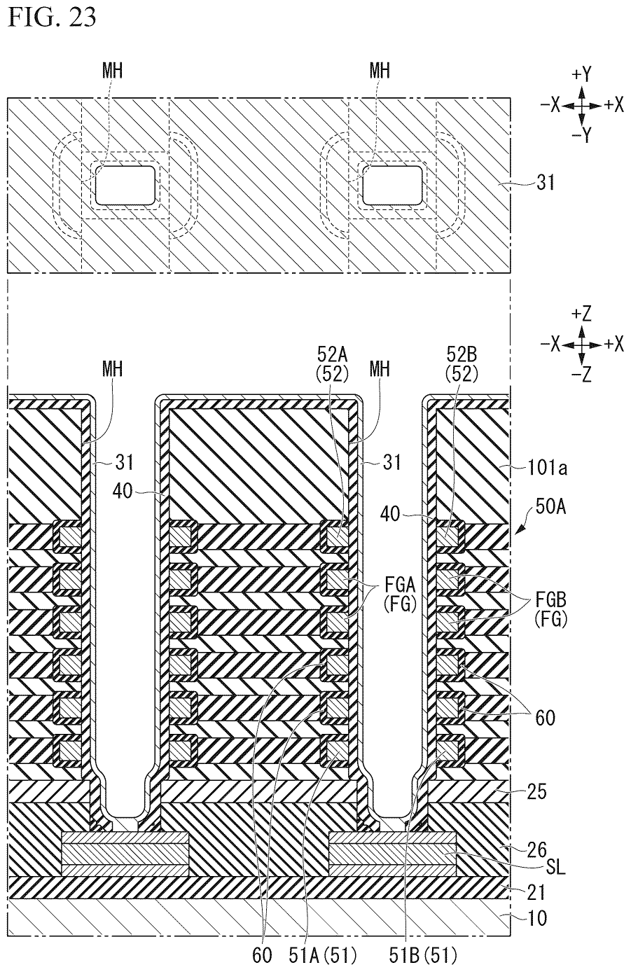

Next, as shown in FIG. 23, a semiconductor material is deposited on an inner circumferential surface of the tunnel insulating film 40 to form the channel portion 31 of the pillar 30. The channel portion 31 may be subjected to an annealing treatment at this time to crystallize the amorphous silicon, or may be subjected to an annealing treatment at a later time.

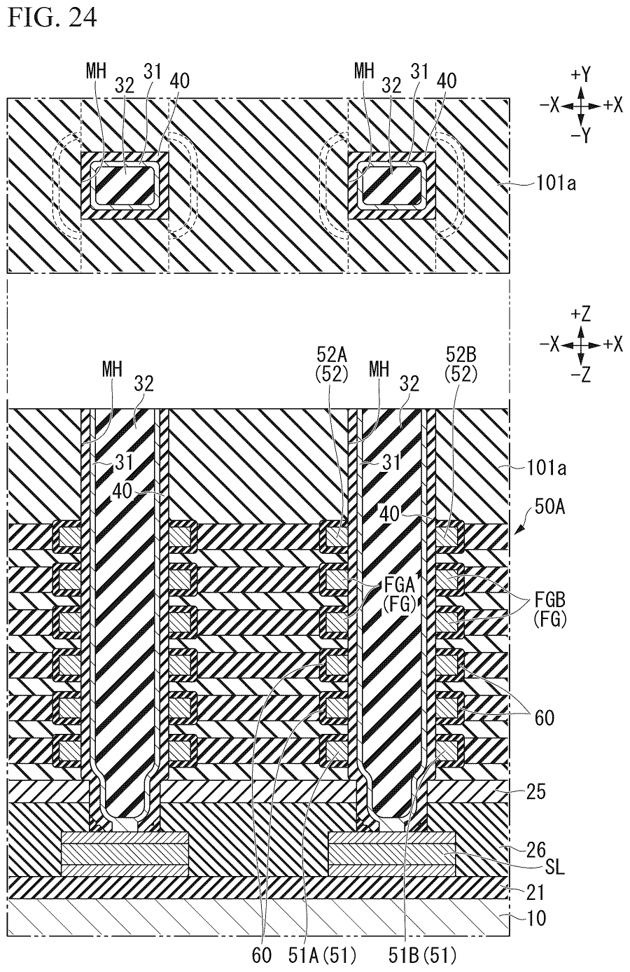

Next, as shown in FIG. 24, for example, silicon oxide is deposited in the memory hole MH to form the insulating core 32 implanted into the inside the memory hole MH. Thereafter, for example, etching is performed to expose upper surfaces of the mask 101a, the channel portion 31, the tunnel insulating film 40, and the insulating core 32.

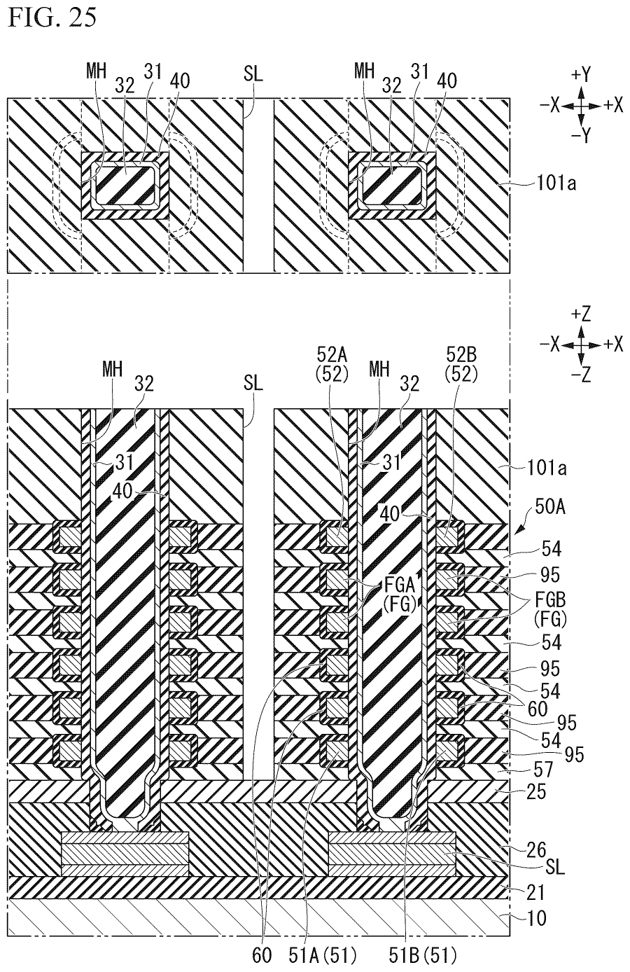

Next, as shown in FIG. 25, a slit SL penetrating the intermediate-multi-layered body 50A in the Z direction is formed.

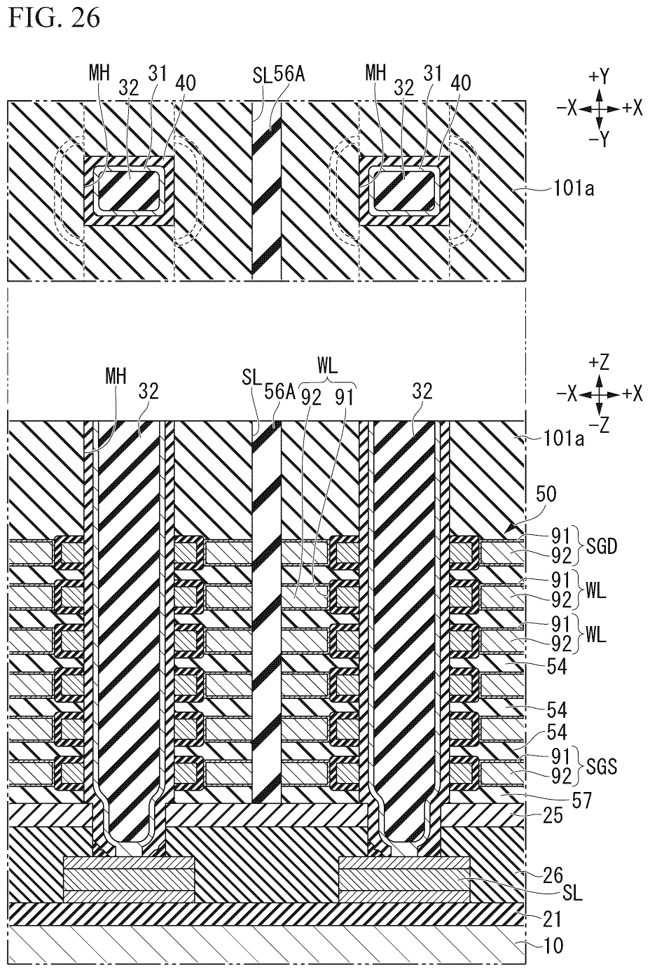

Next, as shown in FIG. 26, the first filling film 95 is replaced with the word line WL. For example, first, the first filling film 95 is removed by wet etching through the slit SL. Wet etching uses an etchant that can etch silicon nitride faster than silicon oxide and polysilicon. Thereafter, the barrier metal film 91 and the conductive member 92 are provided in the space from which the first filling film 95 has been removed, thereby forming the plurality of word lines WL, source-side selection gate lines SGS, and drain-side selection gate lines SGD. Next, the slit SL is filled with an insulating material to form the insulating member 56A.

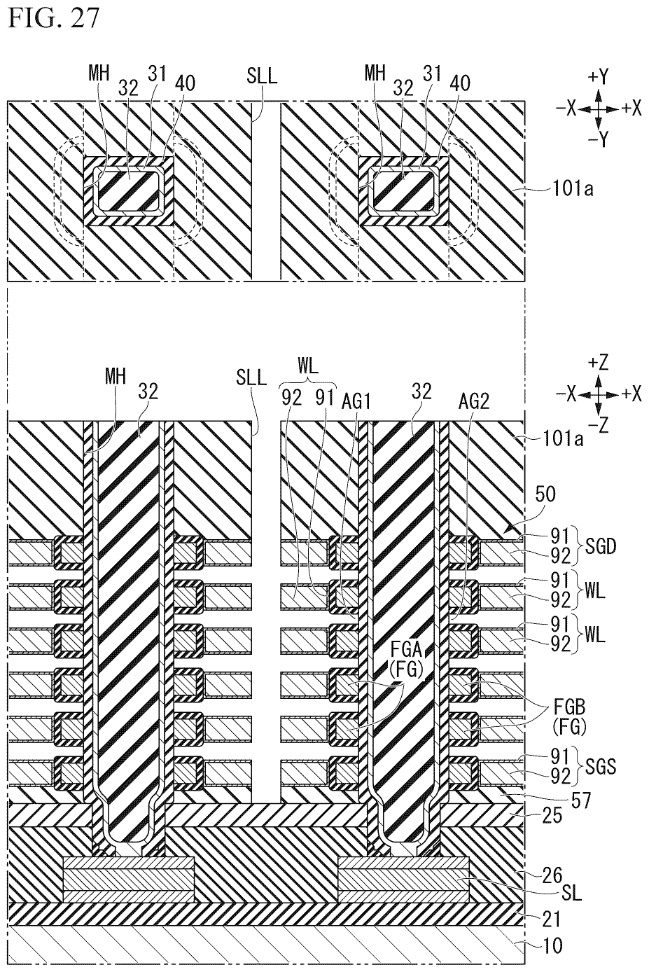

Next, as shown in FIG. 27, a slit SLL penetrating the intermediate-multi-layered body 50A in the Z direction is formed. A position at which the slit SLL is formed may be substantially the same as a position at which the slit SL shown in FIG. 25 is formed. Next, the second filling film 54 is removed by wet etching through the slit SLL. Wet etching uses an etchant that can etch polysilicon faster than silicon oxide. Due to this wet etching, the first gap AG1 and the second gap AG2 are formed between the floating gate electrodes FG adjacent to each other in the Z direction, and a part of the tunnel insulating film 40 is exposed.

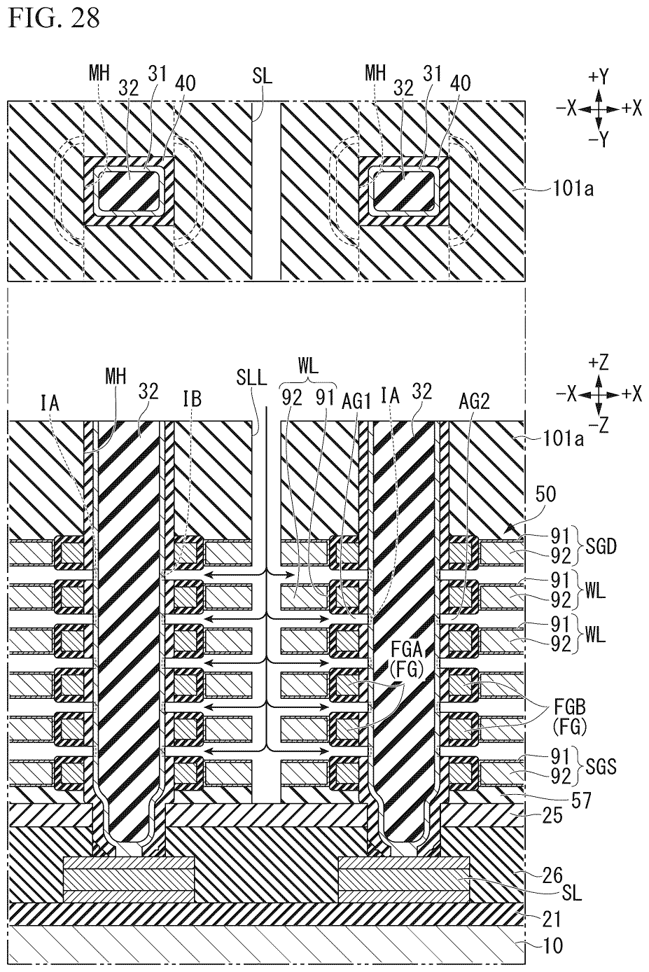

Next, as shown in FIG. 28, the exposed tunnel insulating film 40 is removed to expose a part of the channel 30. Thereafter, an exposed surface of the channel 30 is doped with an n-type impurity gas through the slit SLL, thereby forming the first impurity diffusion region IA and the second impurity diffusion region IB with high impurity concentrations. Thereafter, the intermediate-multi-layered body 50A is subjected to an annealing treatment to activate the first impurity diffusion region IA and the second impurity diffusion region IB.

Next, as shown in FIG. 29, the inside of the slit SLL is filled with an insulating material to form the insulating member 56. Note that, a conductor containing, for example, tungsten may be provided inside the insulating member 56.

Through the processes described above, the intermediate-multi-layered body 50A becomes the multi-layered body 50.

Next, the bit line BL, the plurality of interconnections L1, L2, and L3, the contacts 80, and the like are formed by known methods.

Therefore, the semiconductor storage device 1 is formed. Note that, the manufacturing process shown here is just an example, and other processes may be inserted between the respective processes.

### 5. Modified Example of the Embodiment

Next, a modified example of the embodiment will be described.

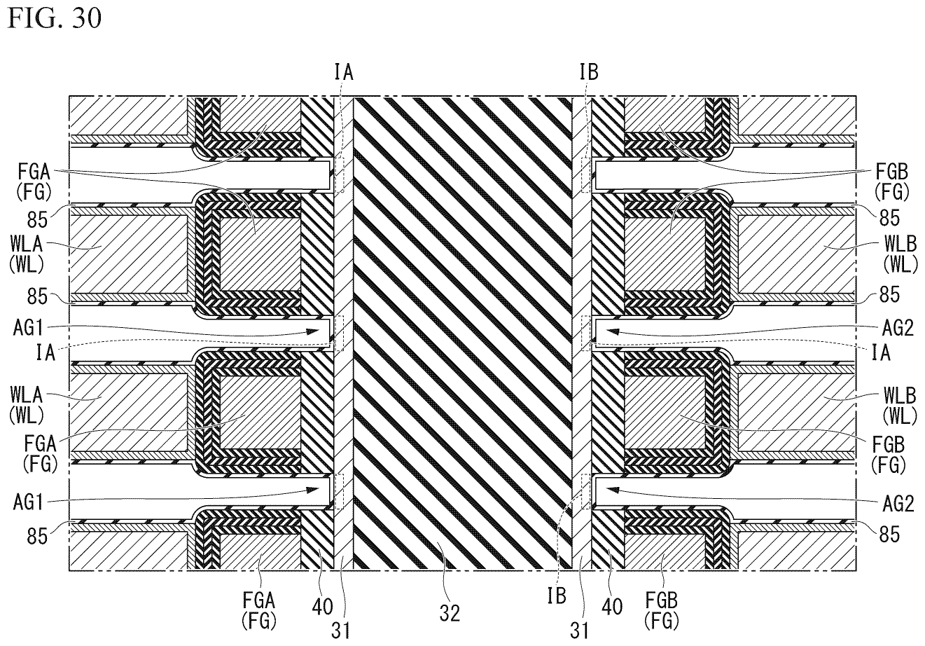

FIG. 30 is a cross-sectional view showing a semiconductor storage device 1A of the present modified example.

This present modified example differs from the present embodiment in that a third insulating film 85 is provided on surfaces in the Z direction of the first word line WLA, the second word line WLB, the first floating gate electrode FGA, and the second floating gate electrode FGB. Also, the third insulating film 85 is provided to cover a surface of the first impurity diffusion region IA on the side of the first gap GA1 and a surface of the second impurity diffusion region IB on the side of the second gap GA2.

Configurations of the present modified example other than those described below are the same as the configurations of the present embodiment.

As described above, when the third insulating film 85 is provided on the surfaces of the first word line WLA, the second word line WLB, the first floating gate electrode FGA, and the second floating gate electrode FGB, and on the exposed surfaces of the first impurity diffusion region IA and the second impurity diffusion region IB, a strength of the entire semiconductor storage device 1A can be secured and the exposed surfaces of the first impurity diffusion region IA and the second impurity diffusion region IB can be protected. As a result, electrical characteristics of the semiconductor storage device 1A can be stabilized.

While some embodiments have been described above, the embodiments are not limited to the above-described examples. For example, the memory film may be a ferroelectric film included in an Ferroelectric FET (FeFET) memory that stores data according to a direction of polarization. The ferroelectric film is formed of, for example, hafnium oxide.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

### REFERENCE SIGNS LIST

1 Semiconductor storage device, 10 Silicon substrate, 30 Pillar, 31 Channel portion, 40 Tunnel insulating film, 40A First tunnel insulating film, 40B Second tunnel insulating film, 60 Block insulating film, FG Floating gate electrode, FGA First floating gate electrode, FGB Second floating gate electrode, WL Word line, WLA First word line, WLB Second word line, SGS Source-side selection gate line, SGD Drain-side selection gate line, IA First impurity diffusion region, IB Second impurity diffusion region

1. A semiconductor storage device comprising:
a substrate;
a first interconnection extending in a first direction;
a second interconnection adjacent to the first interconnection in a second direction intersecting the first direction, extending in the first direction;
a channel portion provided between the first interconnection and the second interconnection, extending in a third direction intersecting the first direction and the second direction;
first charge storage portions provided between the first interconnection and the channel portion;
second charge storage portions provided between the second interconnection and the channel portion;
first insulating films provided between the first charge storage portions and the channel portion; and
second insulating films provided between the second charge storage portions and the channel portion, wherein
the first charge storage portions adjacent to each other in the third direction are provided such that a first gap is formed between the first charge storage portions adjacent to each other in the third direction,
the second charge storage portions adjacent to each other in the third direction are provided such that a second gap is formed between the second charge storage portions adjacent to each other in the third direction,
a first impurity diffusion region in which an impurity element is diffused is provided inside the channel portion between the first charge storage portions adjacent to each other in the third direction, and
a second impurity diffusion region in which an impurity element is diffused is provided inside the channel portion between the second charge storage portions adjacent to each other in the third direction.

2. The semiconductor storage device according to claim 1, wherein
the first impurity diffusion region and the second impurity diffusion region are each exposed at a side surface of the channel portion.

3. The semiconductor storage device according to claim 1, wherein
the impurity element is n-type.

4. The semiconductor storage device according to claim 1, wherein
each of lengths of the first impurity diffusion region and the second impurity diffusion region in the third direction is larger than a distance between the first charge storage portions adjacent to each other in the third direction and a distance between the second charge storage portions adjacent to each other in the third direction.

5. The semiconductor storage device according to claim 1, wherein
each of thicknesses of the first impurity diffusion region and the second impurity diffusion region in the second direction is larger than or equal to half a thickness of the channel portion.

6. The semiconductor storage device according to claim 1, wherein
the first insulating films and the second insulating films are provided intermittently along a side of the channel portion in the third direction.

7. The semiconductor storage device according to claim 1, wherein
a third insulating film is provided to cover surfaces in the third direction of the first interconnection, the second interconnection, the first charge storage portions, and the second charge storage portions, and surfaces on a side of a gap of the first impurity diffusion region and the second impurity diffusion region.
